(19) United States
(12) Patent Application Publication
(10) Pub. No.: US 2024/0290825 A1
(43) Pub. Date: Aug. 29, 2024

(54) SEMICONDUCTOR DEVICE

(71) Applicant: SUMITOMO ELECTRIC INDUSTRIES, LTD., Osaka (JP)

(72) Inventors: Akira MUKAI, Osaka (JP); Masaya OKADA, Osaka (JP); Isao MAKABE, Osaka (JP); Akihiro HAYASAKA, Osaka (JP)

(21) Appl. No.: 18/583,026

(22) Filed: Feb. 21, 2024

(30) Foreign Application Priority Data
Feb. 27, 2023 (JP) 2023-027999

(51) Int. Cl. H01L 29/06; H01L 29/20; H01L 29/778

(52) U.S. Cl. CPC H01L 29/0603; H01L 29/2003; H01L 29/7786

(57) ABSTRACT

A semiconductor device includes a barrier layer having an upper surface with a nitrogen polarity, a channel layer having an upper surface with a nitrogen polarity, provided on the barrier layer, a silicon nitride film provided on the channel layer, a dielectric film provided on the silicon nitride film, and a gate electrode provided on the dielectric film. A relative dielectric constant of the dielectric film is higher than a relative dielectric constant of the silicon nitride film.

### CROSS-REFERENCE TO RELATED APPLICATIONS

This application is based upon and claims priority to Japanese Patent Application No. 2023-027999, filed on Feb. 27, 2023, the entire contents of which are incorporated herein by reference.

### TECHNICAL FIELD

The present disclosure relates to semiconductor devices.

### BACKGROUND

A high electron mobility transistor (HEMT) having a structure in which a channel layer is formed on a barrier layer has been proposed. Further, in order to improve a drain current, a transistor using a dielectric constant film having a relative dielectric constant higher than a relative dielectric constant of silicon nitride (SiN) (hereinafter also referred to as a high dielectric constant film), as a gate insulating film, has also been proposed. The high dielectric constant film is formed by deposition and heat treatment after the deposition.

Examples of related art include Japanese Laid-Open Patent Publication No. 2007-329483, and Japanese Laid-Open Patent Publication No. 2010-510680.

Even if the high dielectric constant film were used for the gate insulating film of the HEMT having the structure in which the channel layer is formed on the barrier layer, it would be difficult to further improve electrical characteristics.

### SUMMARY

One object of the present disclosure is to provide a semiconductor device capable of improving the electrical characteristics.

A semiconductor device according to an embodiment of the present disclosure includes a barrier layer having an upper surface with a nitrogen polarity; a channel layer having an upper surface with a nitrogen polarity, provided on the barrier layer; a silicon nitride film provided on the channel layer; a dielectric film provided on the silicon nitride film; and a gate electrode provided on the dielectric film, wherein a relative dielectric constant of the dielectric film is higher than a relative dielectric constant of the silicon nitride film.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a cross sectional view illustrating a semiconductor device according to one embodiment;

FIG. 2 is a diagram illustrating an example of preferable ranges of thicknesses of a SiN film and a dielectric film;

FIG. 3 is a diagram illustrating a relationship between the thickness of the SiN film and a contribution ratio with respect to a total capacitance;

FIG. 4 is a diagram illustrating a relationship between the thickness of the dielectric film and the contribution ratio with respect to the total capacitance; and

FIG. 5 is a diagram illustrating a measurement result of a signal intensity of Ga atoms.

### DETAILED DESCRIPTION

A description will hereinafter be given of embodiments of the present disclosure with reference to the drawings.

[1] A semiconductor device according to one aspect of the present disclosure includes a barrier layer having an upper surface with a nitrogen polarity; a channel layer having an upper surface with a nitrogen polarity, provided on the barrier layer; a silicon nitride film provided on the channel layer; a dielectric film provided on the silicon nitride film; and a gate electrode provided on the dielectric film, wherein a relative dielectric constant of the dielectric film is higher than a relative dielectric constant of the silicon nitride film.

The present inventors conducted diligent studies to find out the cause of the difficulty in improving the electrical characteristics when the high dielectric constant film is used as the gate insulating film of the conventional HEMT having the structure in which the channel layer is formed on the barrier layer. As a result, it was found that atoms composing the channel layer diffuse into the high dielectric constant film during the heat treatment for forming the high dielectric constant film. It was also found that, in a case where a silicon nitride film is present between the high dielectric constant film and the channel layer, the diffusion of the atoms composing the channel layer is reduced.

As described above, the semiconductor device according to one aspect of the present disclosure includes the silicon nitride film provided on the channel layer, the dielectric film provided on the silicon nitride film, and the gate electrode provided on the dielectric film. In addition, the relative dielectric constant of the dielectric film is higher than the relative dielectric constant of the silicon nitride film. For this reason, a large drain current can be obtained, and a deterioration in the electrical characteristics caused by the diffusion of the atoms composing the channel layer can be reduced. Accordingly, the electrical characteristics can be improved.

[2] In the [1], the silicon nitride film may have a thickness greater than or equal to 1 nm. In this case, the silicon nitride film can easily be formed with a good coverage.

[3] In [1] or [2], a first capacitance of the dielectric film may be less than or equal to a second capacitance of the silicon nitride film along a thickness direction. In this case, a high capacitance can easily be obtained in a laminated body of the silicon nitride film and the dielectric film.

[4] In any one of [1] to [3], a third capacitance between the upper surface of the barrier layer and a lower surface of the silicon nitride film may be less than or equal to a second capacitance of the silicon nitride film along a thickness direction. In this case, the capacitance between the gate electrode and the barrier layer can easily be adjusted by the third capacitance including the capacitance of the channel layer.

[5] In any one of [1] to [4], a third capacitance between the upper surface of the barrier layer and a lower surface of the silicon nitride film may be less than or equal to the first capacitance of the dielectric film along a thickness direction. In this case, the capacitance between the gate electrode and the barrier layer can easily be adjusted by the third capacitance including the capacitance of the channel layer.

[6] In any one of [1] to [5], the semiconductor device may further include a cap layer including a third nitride semiconductor between the channel layer and the silicon nitride film. In this case, a concentration of two-dimensional electron gas can easily be stabilized.

[7] In any one of [1] to [6], the dielectric film may include at least one element selected from a group consisting of hafnium, lanthanum, and zirconium. In this case, a high relative dielectric constant can easily be obtained in the dielectric film.

[8] In any one of [1] to [7], the silicon nitride film may have a thickness less than or equal to 10 nm. In this case, the capacitance between the gate electrode and the barrier layer can easily be adjusted by the third capacitance including the capacitance of the channel layer.

[9] In any one of [1] to [8], the semiconductor device may further include a first recess and a second recess provided in at least the channel layer; a first nitride semiconductor layer, provided inside the first recess, and having an electrical resistance lower than an electrical resistance of the channel layer; a second nitride semiconductor layer, provided in the second recess, and having an electrical resistance lower than the electrical resistance of the channel layer; a source electrode making an ohmic contact with the first nitride semiconductor layer; and a drain electrode making an ohmic contact with the second nitride semiconductor layer. In this case, the electrical resistance between the source electrode and the two-dimensional electron gas, and the electrical resistance between the drain electrode and the two-dimensional electron gas, can be reduced. The first recess and the second recess may be formed in the channel layer and in the barrier layer.

[10] A semiconductor device according to another aspect of the present disclosure includes a barrier layer having an upper surface with a nitrogen polarity; a channel layer having an upper surface with a nitrogen polarity, provided on the barrier layer; a silicon nitride film provided on the channel layer; a dielectric film provided on the silicon nitride film; a gate electrode provided on the dielectric film; a first recess and a second recess provided in the channel layer and in the barrier layer; a first nitride semiconductor layer, provided inside the first recess, and having an electrical resistance lower than an electrical resistance of the channel layer; a second nitride semiconductor layer, provided inside the second recess, and having an electrical resistance lower than the electrical resistance of the channel layer; a source electrode making an ohmic contact with the first nitride semiconductor layer; and a drain electrode making an ohmic contact with the second nitride semiconductor layer, wherein a relative dielectric constant of the dielectric film is higher than a relative dielectric constant of the silicon nitride film, the dielectric film includes at least one element selected from a group consisting of hafnium, lanthanum, and zirconium, the silicon nitride film has a thickness greater than or equal to 1 nm, a first capacitance of the dielectric film is less than or equal to a second capacitance of the silicon nitride film along a thickness direction, a third capacitance between the upper surface of the barrier layer and a lower surface of the silicon nitride film is less than or equal to the second capacitance of the silicon nitride film along a thickness direction, and the third capacitance less than or equal to the first capacitance.

In this case, it is also possible to obtain a large drain current, and reduce the deterioration of the electrical characteristics caused by the diffusion of the atoms composing the channel layer. Accordingly, the electrical characteristics can be improved.

### Details of Embodiments of the Present Disclosure

Hereinafter, embodiments of the present disclosure will be described in detail, but the present disclosure is not limited thereto. In the present specification and drawings, constituent elements having substantially the same functional configuration are designated by the same reference numerals, and a redundant description thereof may be omitted. In the present disclosure, “a plan view” refers to a view of an object from above the object.

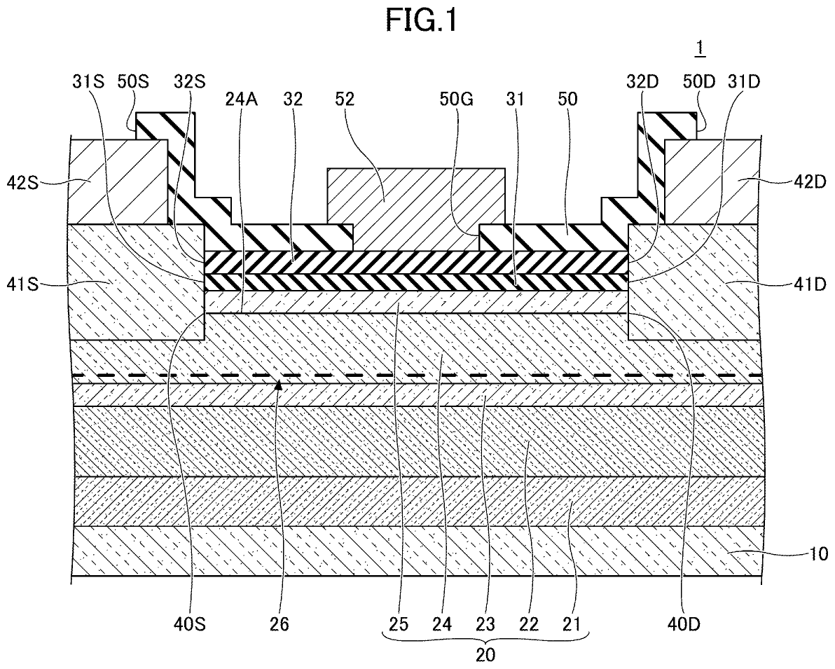

The embodiments relate to a semiconductor device including a GaN-based high electron mobility transistor (HEMT). FIG. 1 is a cross sectional view illustrating a semiconductor device according to one embodiment.

As illustrated in FIG. 1, a semiconductor device 1 according to the embodiment mainly includes a substrate 10, an epitaxial layer 20, a silicon nitride (SiN) film 31, a dielectric film 32, a regrowth layer 41S, a regrowth layer 41D, a passivation film 50, a gate electrode 52, a source electrode 42S, and a drain electrode 42D.

The substrate 10 is a substrate for growing a gallium nitride based (GaN-based) semiconductor layer, for example, and is a semi-insulating SiC substrate, for example. In a case where the substrate 10 is the SiC substrate, an upper surface of the substrate 10 is a carbon (C) polar plane. In a case where the surface of the substrate 10 is a C polar surface, the epitaxial layer 5, 20 can be formed by crystal growth on a nitrogen (N) polar surface as a growth surface.

The epitaxial layer 20 includes a buffer layer 21, a barrier layer 22, a spacer layer 23, a channel layer 24, and a cap layer 25.

The buffer layer 21 is provided on the substrate 10. The buffer layer 21 is an aluminum nitride (AlN) layer, for example. The AlN layer has a thickness in a range greater than or equal to 5 nm and less than or equal to 100 nm, for example. The buffer layer 21 may include a AlN layer, and a GaN layer or an aluminum gallium nitride (AlGaN) layer provided on the AlN layer.

The barrier layer 22 is provided on the buffer layer 21. The barrier layer 22 is a AlGaN layer, for example. A band gap of the barrier layer 22 is larger than a band gap of the channel layer 24. The barrier layer 22 has a thickness in a range greater than or equal to 5 nm and less than or equal to 50 nm, for example. A composition of the barrier layer 22 is Al_{y}Ga_{1-y}N (0.15<=Y<=0.55), for example. A conductivity type of the barrier layer 22 is n-type or undoped (i-type), for example. An indium aluminum nitride (InAlN) layer or an indium aluminum gallium nitride (InAlGaN) layer may be used in place of the AlGaN layer.

The spacer layer 23 is provided on the barrier layer 22. The spacer layer 23 is a AlN layer, for example. The spacer layer 23 has a thickness in a range greater than or equal to 0.5 nm and less than or equal to 3.0 nm, for example.

The channel layer 24 is provided on the spacer layer 23. The channel layer 24 is a GaN layer, for example. The band gap of the channel layer 24 is smaller than the band gap of the barrier layer 22. The channel layer 24 has a thickness in a range greater than or equal to 5 nm and less than or equal to 30 nm, for example. Strain is generated between the channel layer 24 and the barrier layer 22 and between the channel layer 24 and the spacer layer 23 due to differences in lattice constants between the channel layer 24 and the barrier layer 22 and between the channel layer 24 and the spacer layer 23, and this strain induces a piezoelectric charge at an interface between the channel layer 24 and the barrier layer 22 and between the channel layer 24 and the spacer layer 23. As a result, the density of two-dimensional electron gas (2DEG) is enhanced in a region (channel region 26) of the channel layer 24 on the side closer to the barrier layer 22. A conductivity type of the channel layer 24 is the n-type or undoped (i-type), for example.

The cap layer 25 is provided on the channel layer 24. The cap layer 25 is a AlGaN layer, for example. The AlGaN layer is an example of a third nitride semiconductor layer. The cap layer 25 has a thickness in a range greater than or equal to 1 nm and less than or equal to 5 nm, for example.

The buffer layer 21, the barrier layer 22, the spacer layer 23, the channel layer 24, and the cap layer are formed by crystal growth on the N polar surface as the growth surface, on the C polar surface of the SiC substrate. Accordingly, upper surfaces of the buffer layer 21, the barrier layer 22, the spacer layer 23, the channel layer 24, and the cap layer 25 on the substrate 10 have the N polarity, and lower surfaces of the buffer layer 21, the barrier layer 22, the spacer layer 23, the channel layer 24, and the cap layer 25 on the substrate 10 have a gallium (Ga) polarity.

A first recess 40S for a source and a second recess 40D for a drain are formed in the epitaxial layer 20. A bottom of the first recess 40S and a bottom of the second recess 40D are closer to the lower surface of the epitaxial layer 20 than to an upper surface 24A of the channel layer 24. That is, the first recess 40S and the second recess 40D are formed to a depth deeper than the upper surface 24A of the channel layer 24. The bottom of the first recess 40S and the bottom of the second recess 40D may be located in the channel layer 24, or in the spacer layer 23, or in the barrier layer 22.

The SiN film 31 is provided on the epitaxial layer 20. The SiN film 31 makes contact with the upper surface of the epitaxial layer 20. The SiN film 31 has a thickness in a range greater than or equal to 1 nm and less than or equal to 10 nm, for example. A first opening 31S for the source and a second opening 31D for the drain are formed in the SiN film 31. The first opening 31S is connected to the first recess 40S, and the second opening 31D is connected to the second recess 40D.

The dielectric film 32 is provided on the SiN film 31. The dielectric film 32 makes contact with the upper surface of the SiN film 31. The SiN film 31 is provided between the epitaxial layer 20 and the dielectric film 32, and the dielectric film 32 is separated from the epitaxial layer 20 by the SiN film 31. A relative dielectric constant of the dielectric film 32 is higher than a relative dielectric constant of the SiN film 31. The relative dielectric constant of the dielectric film 32 is higher than 7.8, for example. The dielectric film 32 may include at least one element selected from a group consisting of hafnium, lanthanum, and zirconium. For example, the dielectric film 32 is a hafnium silicate (HfSiOₓ) film, and the relative dielectric constant of the dielectric film 32 is approximately 13.5. The dielectric film 32 has a thickness in a range greater than or equal to 3 nm and less than or equal to 15 nm, for example. A third opening 32S for the source and a fourth opening 32D for the drain are formed in the dielectric film 32. The third opening 32S is connected to the first opening 315, and the fourth opening 32D is connected to the second opening 31D.

The regrowth layer 41S is provided on the channel layer 24, or the spacer layer 23, or the barrier layer 22, inside the first recess 405. The regrowth layer 41D is provided on the channel layer 24, or the spacer layer 23, or the barrier layer 22, inside the second recess 40D. The regrowth layer 41S and the regrowth layer 41D are n-type GaN layers, for example. The regrowth layer 41S and the regrowth layer 41D includes Ge or Si as an n-type impurity. Electrical resistances of the regrowth layer 41S and the regrowth layer 41D are lower than an electrical resistance of the channel layer 24. For example, the regrowth layer 41S and the regrowth layer 41D are formed by a regrowth of an n-type GaN layer after forming the first recess 40S and the second recess 40D in the epitaxial layer 20. The regrowth layer 41S is an example of a first nitride semiconductor layer, and the regrowth layer 41D is an example of a second nitride semiconductor layer.

The source electrode 42S is provided on the regrowth layer 41S, and the drain electrode 42D is provided on the regrowth layer 41D. In the plan view, the source electrode 42S is located on an inner side of the first recess 40S, the first opening 31S, and the third opening 32S, and the drain electrode 42D is located on an inner side of the second recess 40D, the second opening 31D, and the fourth opening 32D. The source electrode 42S makes contact with the regrowth layer 41S, and the drain electrode 42D makes contact with the regrowth layer 41D. The source electrode 42S makes an ohmic contact with the regrowth layer 41S, and the drain electrode 42D makes an ohmic contact with the regrowth layer 41D.

The passivation film 50 covers the dielectric film 32, the regrowth layer 41S, the regrowth layer 41D, the source electrodes 42S, and the drain electrode 42D. The passivation film 50 is a SiN film, for example. The passivation film 50 has a thickness in a range greater than or equal to 5 nm and less than or equal to 50 nm in a portion on the dielectric film 32 where the passivation film 50 has a uniform thickness, for example. A fifth opening 50S for the source, a sixth opening 50D for the drain, and a seventh opening 50G for a gate are formed in the passivation film 50. A portion of the source electrode 42S is exposed through the fifth opening 50S, and a portion of the drain electrode 42D is exposed through the sixth opening 50D. In the plan view, the seventh opening 50G is located between the fifth opening 50S and the sixth opening 50D. A portion of the dielectric film 32 is exposed through the seventh opening 50G.

In the plan view, the gate electrode 52 is located between the source electrode 42S and the drain electrode 42D. The gate electrode 52 is provided on the passivation film 50, and makes contact with the dielectric film 32 through the seventh opening 50G.

In the semiconductor device 1 according to the embodiment, because the dielectric film 32 is provided between the epitaxial layer 20 and the gate electrode 52, it is possible to reduce a leakage current between the channel region 26 and the gate electrode 52, and expand a range in which a gate voltage can be modulated.

Accordingly, a large drain current can be obtained. In addition, because the SiN film 31 is provided between the epitaxial layer 20 and the dielectric film 32, it is possible to reduce diffusion of atoms composing the epitaxial layer 20, that is, Ga atoms in this example, into the dielectric film 32. Hence, according to the semiconductor device 1, electrical characteristics can be improved.

The provision of the cap layer 25 facilitates obtaining a good flatness at the interface between the epitaxial layer 20 and the SiN film 31, and a concentration of the 2DEG can easily be stabilized.

Because the dielectric film 32 includes at least one element selected from the group consisting of hafnium, lanthanum, and zirconium, a high relative dielectric constant can easily be obtained for the dielectric film 32.

Moreover, because the source electrode 42S makes the ohmic contact with the regrowth layer 41S, and the drain electrode 42D makes the ohmic contact with the regrowth layer 41D, the electric resistance between the 2DEG and each of the source electrode and the drain electrode can be reduced.

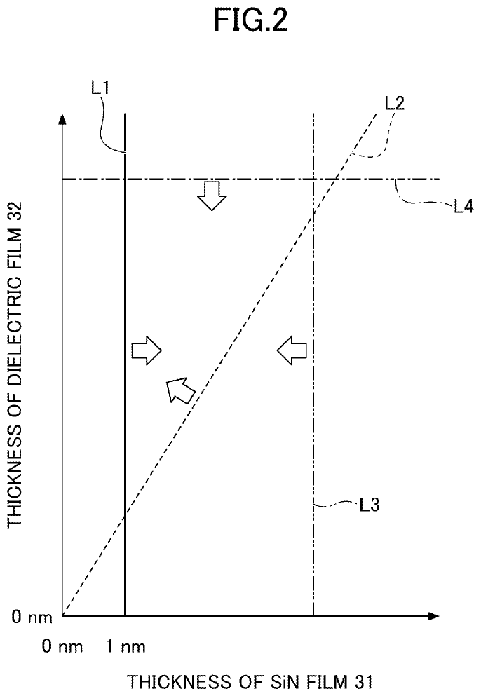

Next, thicknesses of the SiN film 31 and the dielectric film 32 and a capacitance between the gate electrode 52 and the channel region 26 will be described. FIG. 2 is a diagram illustrating an example of preferable ranges of the thicknesses of the SiN film 31 and the dielectric film 32.

If the thickness of the SiN film 31 is less than 1 nm, the coverage of the SiN film 31 may be deteriorated. For this reason, the thickness of the SiN film 31 is preferably greater than or equal to 1 nm for reducing diffusion of the Ga atoms into the dielectric film 32. In FIG. 2, a straight line L1 indicated by a solid line is a straight line formed by a set of points at which the thickness of the SiN film 31 becomes 1 nm.

When a capacitance of the channel layer 24 is denoted by C24, a capacitance of the cap layer 25 is denoted by C25, a capacitance of the SiN film 31 is denoted by C31, a capacitance of the dielectric film 32 is denoted by C32, and a capacitance between the gate electrode 52 and the barrier layer 22 is denoted by C in a thickness direction, respectively, the following formula (1) stands.

$$1 / C = 1 / C 24 + 1 / C 25 + 1 / C 31 + 1 / C 32 \qquad ( 1 )$$

Contribution ratios of the capacitance C24, the capacitance C25, the capacitance C31, and the capacitance C32 with respect to the capacitance C are obtained from the formula (1). When a composition of the channel layer 24 is identified, a relative dielectric constant E24 of the channel layer 24 can be identified, and when the relative dielectric constant E24 of the channel layer 24 can be identified, the capacitance C24 of the channel layer 24 can be identified using a thickness T24 and an area S24 of the channel layer 24. When a composition of the cap layer 25 is identified, a relative dielectric constant E25 of the cap layer 25 can be identified, and when the relative dielectric constant E25 of the cap layer can be identified, the capacitance C25 of the cap layer can be identified using a thickness T25 and an area S25 of the cap layer 25. When a composition of the SiN film 31 is identified, a relative dielectric constant E31 of the SiN film 31 can be identified, and when the relative dielectric constant E31 of the SiN film 31 can be identified, the capacitance C31 of the SiN film 31 can be identified using a thickness T31 and an area S31 of the SiN film 31. When a composition of the dielectric film 32 is identified, a relative dielectric constant E32 of the dielectric film 32 can be identified, and when the relative dielectric constant E32 of the dielectric film 32 can be identified, the capacitance C32 of the dielectric film 32 can be identified using a thickness T32 and an area S32 of the dielectric film 32. In this case, the contribution ratio refers to a ratio of the capacitance of each component with respect to a total capacitance, and for example, the contribution ratio of the channel layer 24 is determined by the following formula (2). The same applies to the other capacitance components.

$$Contribution ratio of channel layer 24 = 100 \times C / C 24 \qquad ( 2 )$$

In the description below, each capacitance is assumed to be a capacitance per unit area for simplification, namely the areas S24, S25, S31, and S32 are assumed to be equal to each other. When the SiN film 31 has a thickness greater than 10 nm, the capacitance C31 may become too small, and the contribution ratio of the capacitance C31 may become too high. For this reason, the thickness T31 of the SiN film 31 is set to be preferably less than or equal to 10 nm, more preferably less than or equal to 9 nm, and still more preferably less than or equal to 7 nm. In addition, when the thickness T31 of the SiN film 31 is set to be less than or equal to 10 nm, the capacitance C between the gate electrode 52 and the barrier layer 22 can easily be adjusted by a third capacitance C30 between the upper surface of the barrier layer 22 and the lower surface of the SiN film 31. The third capacitance C30 includes the capacitance C24 of the channel layer 24, and the capacitance C25 of the cap layer 25. For example, the third capacitance C30 can be estimated by using a formula 1/C30=1/C24+1/C25.

The capacitance C32 of the dielectric film 32 is preferably less than or equal to the capacitance C31 of the SiN film 31. In other words, the thickness T32 of the dielectric film 32 is preferably greater than or equal to the thickness at which the capacitance C32 of the dielectric film 32 becomes equal to the capacitance C31 of the SiN film 31. When the capacitance C32 of the dielectric film 32 is equal to the capacitance C31 of the SiN film 31, the thickness T32 of the dielectric film 32 becomes E32/E31 times the thickness T31. In this case, a high capacitance can easily be obtained in a laminated body of the SiN film 31 and the dielectric film 32. The capacitance C32 is an example of a first capacitance, and the capacitance C31 is an example of a second capacitance. In FIG. 2, a straight line L2 indicated by a broken line is a straight line formed of a set of points at which the first capacitance becomes equal to the second capacitance.

The third capacitance C30 between the upper surface of the barrier layer 22 and the lower surface of the SiN film 31 is preferably less than or equal to the capacitance C31 of the SiN film 31. In other words, the thickness T31 of the SiN film 31 is preferably less than or equal to the thickness at which the capacitance C31 of the SiN film 31 becomes equal to the third capacitance C30. In this case, the capacitance C between the gate electrode 52 and the barrier layer 22 can easily be adjusted by the third capacitance C30. In FIG. 2, a straight line L3 indicated by a two-dot chain line is a straight line formed of a set of points at which the second capacitance becomes equal to the third capacitance.

The third capacitance C30 between the upper surface of the barrier layer 22 and the lower surface of the SiN film 31 is preferably less than or equal to the capacitance C32 of the dielectric film 32. In other words, the thickness T32 of the dielectric film 32 is preferably less than or equal to the thickness at which the capacitance C32 of the dielectric film 32 becomes equal to the third capacitance C30. In this case, the capacitance C between the gate electrode 52 and the barrier layer 22 can also be easily adjusted by the third capacitance C30. In FIG. 2, a straight line L4 indicated by a one-dot chain line is a straight line formed of a set of points at which the first capacitance becomes equal to the third capacitance.

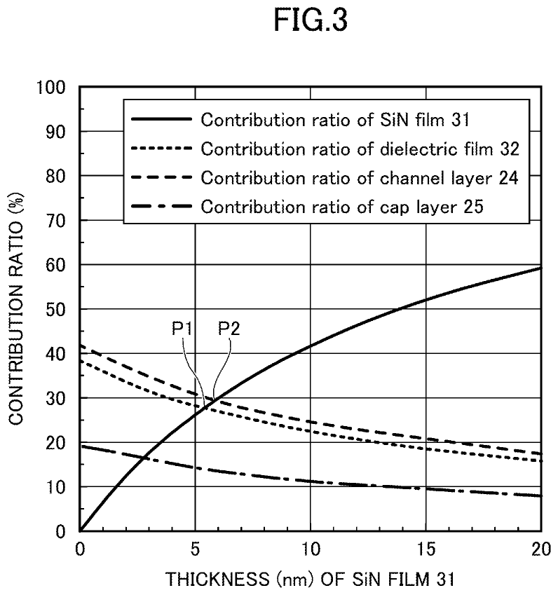

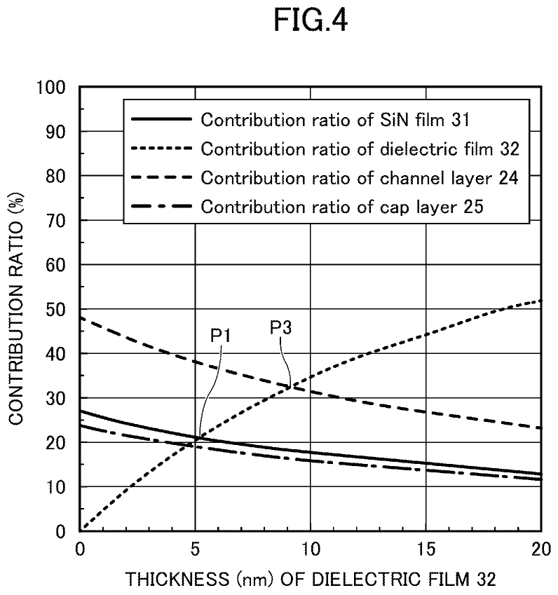

FIG. 3 illustrates a relationship between the thickness T31 of the SiN film 31 and the contribution ratio of each capacitance with respect to the total capacitance, in a case where the channel layer 24 is a GaN layer having a thickness of 10 nm, the cap layer 25 is a Al_{0.2}Ga_{0.8}N layer having a thickness of 3 nm, and the dielectric film 32 has a relative dielectric constant of 13.5 and a thickness of 10 nm. FIG. 4 illustrates a relationship between the thickness T32 of the dielectric film 32 and the contribution ratio of each capacitance with respect to the capacitance C, in a case where the channel layer 24 is a GaN layer having a thickness of 10 nm, the cap layer 25 is a Al_{0.2}Ga_{0.8}N layer having a thickness of 3 nm, and the SiN film 31 has a thickness of 3 nm. Calculation of the capacitance of the channel layer 24 includes an influence of quantum displacement.

In this example, an intersection P1 of a curve indicating “the contribution ratio of the SiN film 31” and a curve indicating the “contribution ratio of the dielectric film 32” in FIG. 3 and FIG. 4 corresponds to a point on the straight line L2 in FIG. 2. An intersection P2 of the curve indicating “the contribution ratio of the SiN film 31” and a curve indicating “the contribution ratio of the channel layer 24” in FIG. 3 corresponds to a point on the straight line L3 in FIG. 2. An intersection P3 of the curve indicating the “contribution ratio of the dielectric film 32” and the curve indicating “the contribution ratio of the channel layer 24” in FIG. 4 corresponds to a point on the straight line L4 in FIG. 2.

Next, an experiment related to the diffusion of the Ga atoms conducted by the present inventors will be described. In this experiment, a sample A according to the embodiment, and a sample B having the same structure as the sample A except that no SiN film 31 is provided, were fabricated, and an extent of diffusion of the Ga atoms into the insulating film was measured. A hafnium silicate film was formed as the dielectric film 32, and a heat treatment at 800° C. was performed when forming the hafnium silicate film.

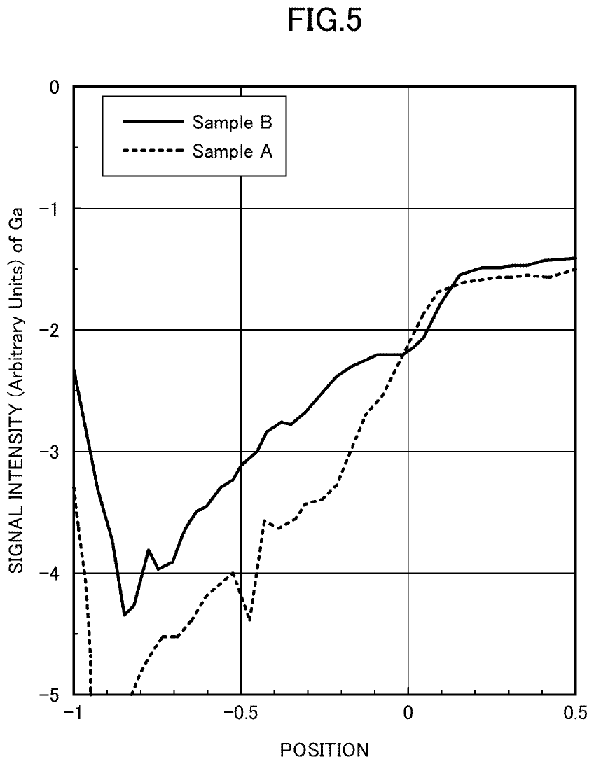

For the sample A, a signal intensity of the Ga atoms in the laminated body of the SiN film 31 and the dielectric film 32 was measured by time-of-flight secondary ion mass spectrometry (TOF-SIMS). For the sample B, the signal intensity of the Ga atoms in a laminated body of the dielectric film 32 was measured by TOF-SIMS. Results of the measurements are illustrated in FIG. 5. The abscissa in FIG. 5 indicates a position with the lower surface of the insulating film regarded as 0 and a direction toward the substrate 10 regarded as positive. In addition, the position is standardized by the thickness of the insulating film. The ordinate in FIG. 5 indicates the signal intensity of the Ga atoms measured by the TOF-SIMS.

As illustrated in FIG. 5, the signal intensity of the Ga atoms in the insulating film was lower in the sample A including the SiN film 31 than in the sample B not including the SiN film 31. This indicates that the diffusion of the Ga atoms is reduced by the SiN film 31.

According to the present disclosure, electrical characteristics can be improved.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a barrier layer having an upper surface with a nitrogen polarity;
a channel layer having an upper surface with a nitrogen polarity, provided on the barrier layer;
a silicon nitride film provided on the channel layer;
a dielectric film provided on the silicon nitride film; and
a gate electrode provided on the dielectric film,
wherein a relative dielectric constant of the dielectric film is higher than a relative dielectric constant of the silicon nitride film.

2. The semiconductor device as claimed in claim 1, wherein the silicon nitride film has a thickness greater than or equal to 1 nm.

3. The semiconductor device as claimed in claim 1, wherein a first capacitance of the dielectric film is less than or equal to a second capacitance of the silicon nitride film along a thickness direction.

4. The semiconductor device as claimed in claim 1, wherein a third capacitance between the upper surface of the barrier layer and a lower surface of the silicon nitride film is less than or equal to a second capacitance of the silicon nitride film along a thickness direction.

5. The semiconductor device as claimed in claim 1, wherein a third capacitance between the upper surface of the barrier layer and a lower surface of the silicon nitride film is less than or equal to the first capacitance of the dielectric film along a thickness direction.

6. The semiconductor device as claimed in claim 1, further comprising:
a cap layer including a third nitride semiconductor between the channel layer and the silicon nitride film.

7. The semiconductor device as claimed in claim 1, wherein the dielectric film includes at least one element selected from a group consisting of hafnium, lanthanum, and zirconium.

8. The semiconductor device as claimed in claim 1, wherein the silicon nitride film has a thickness less than or equal to 10 nm.

9. The semiconductor device as claimed in claim 1, further comprising:
a first recess and a second recess provided in at least the channel layer;
a first nitride semiconductor layer, provided inside the first recess, and having an electrical resistance lower than an electrical resistance of the channel layer;
a second nitride semiconductor layer, provided in the second recess, and having an electrical resistance lower than the electrical resistance of the channel layer;
a source electrode making an ohmic contact with the first nitride semiconductor layer; and
a drain electrode making an ohmic contact with the second nitride semiconductor layer.

10. A semiconductor device comprising:
a barrier layer having an upper surface with a nitrogen polarity;
a channel layer having an upper surface with a nitrogen polarity, provided on the barrier layer;
a silicon nitride film provided on the channel layer;
a dielectric film provided on the silicon nitride film;
a gate electrode provided on the dielectric film;
a first recess and a second recess provided in the channel layer and in the barrier layer;
a first nitride semiconductor layer, provided inside the first recess, and having an electrical resistance lower than an electrical resistance of the channel layer;
a second nitride semiconductor layer, provided inside the second recess, and having an electrical resistance lower than the electrical resistance of the channel layer;
a source electrode making an ohmic contact with the first nitride semiconductor layer; and
a drain electrode making an ohmic contact with the second nitride semiconductor layer, wherein
a relative dielectric constant of the dielectric film is higher than a relative dielectric constant of the silicon nitride film,
the dielectric film includes at least one element selected from a group consisting of hafnium, lanthanum, and zirconium,
the silicon nitride film has a thickness greater than or equal to 1 nm,
a first capacitance of the dielectric film is less than or equal to a second capacitance of the silicon nitride film along a thickness direction,
a third capacitance between the upper surface of the barrier layer and a lower surface of the silicon nitride film is less than or equal to the second capacitance of the silicon nitride film along a thickness direction, and
the third capacitance less than or equal to the first capacitance.
